(19) United States
(12) Patent Application Publication
(10) Pub. No.: US 2024/0274457 A1
(43) Pub. Date: Aug. 15, 2024

(54) HOLDING DEVICE FOR HOLDING A STRUCTURAL PART AND METHOD FOR MANUFACTURING THE HOLDING DEVICE

(71) Applicant: ASML NETHERLANDS B.V., Veldhoven (NL)

(72) Inventors: Nicholas Alan Allsop, Berlin (DE); Benedikt Schmidt, Osnabrück (DE); Constans Mathias Weber, Berlin (DE); Till Warming, Berlin (DE); Jianqiang Zhu, Heeze (NL); Milad Mokhtari, Eindhoven (NL); Antonius Hubertus Van Schijndel, Riethoven (NL)

(21) Appl. No.: 18/569,484

(22) PCT Filed: Jun. 17, 2022
(86) PCT No.: PCT/EP2022/066538

§ 371 Date: Dec. 12, 2023

(30) Foreign Application Priority Data
Jun. 21, 2021 (DE) 10 2021 115 970.9

(51) Int. Cl. H01L 21/683; B25B 11/00

(52) U.S. Cl. CPC H01L 21/6833; B25B 11/00; H01L 21/6838

(57) ABSTRACT

A holding device (100) for holding a structural part, in particular a semiconductor wafer (1) or a lithography mask, comprises a base body (10), which is formed from at least one board (11) with an upper side, and a plurality of protruding studs (12), which are arranged on the upper side of the board (11) and form a contact surface (13) with a predetermined flatness for contacting the structural part, wherein on the upper side of the board (11) a notch absorption layer (21) is provided, which has such a low volume density that the notch absorption layer (21) can be compressed by a compaction in the layer volume in the case of mechanical actions by foreign particles (2), without compromising the flatness of the contact surface (13). A method for manufacturing a holding device (100) for holding a structural part is also described.

### CROSS-REFERENCE TO RELATED APPLICATIONS

This application claims priority of DE application 102021115970.9 which was filed on Jun. 21, 2021 and which is incorporated herein in its entirety by reference.

### FIELD

The invention relates to a holding device, which is adapted to hold a disc-shaped structural part, in particular a semiconductor wafer or a lithography mask, and to a method for manufacturing such a holding device. The invention relates in particular to a wafer clamp or mask clamp or wafer chuck or mask chuck for the holding of semiconductor wafers or lithography masks when they are processed, and to methods for manufacturing them. Applications of the invention arise in the processing of structural parts, especially semiconductor wafers.

### BACKGROUND

In the present description, reference is made to the following prior art, which represents the technical

### BACKGROUND OF THE INVENTION

[1] U.S. Pat. No. 4,502,094;

[2] US 2013/0308116 A1;

[3] WO 2020135971 A1;

[4] US 20150311108 A1;

[5] US 20140368804 A1;

[6] JP 2015167159 A; and

[7] DE 202009007494 U1.

### SUMMARY

It is generally known that holding devices are used for holding disc-shaped or board-shaped structural parts, for example for holding semiconductor wafers, in particular silicon wafers, in lithographic semiconductor processing (chip production). Depending on the holding force exerted, a distinction is made in particular between electrostatic holding devices for electrostatically holding the structural parts and vacuum holding devices for holding the structural parts under the effect of a negative pressure.

Typically, for example, the electrostatic holding device has a base body with several board- or layer-shaped elements (see, for example, [1], [2]), of which at least one board-shaped element is equipped with an electrode apparatus with which the electrostatic holding force is generated. At least one board-shaped element is manufactured from a mechanically rigid ceramic to fulfil a carrying and cooling function. Furthermore, an electrostatic holding device typically has at least one exposed surface, for example on its upper side, which is formed by a plurality of protruding studs. End faces of the studs form a contact surface for the structural part to be held.

For use in chip production, the contact surface spanned by the studs should be as flat as possible, because unevennesses can lead to bending of the held semiconductor wafer and thus to errors in its structuring in chip production, for example. Localised unevennesses of a few nanometers, for example protruding studs >10 nm, can already lead to intolerable bending of the semiconductor wafers.

The flatness of the contact surface spanned by the end faces of the studs may be compromised by a notch on the surface of the holding device. A notch may be caused by a mechanical influence, such as by a foreign particle (notch damage), for example. The notch may be caused, for example, on the end face of a stud by sharp or pointed particles which adhere to the rear side of a semiconductor wafer when it is pressed against the contact surface during processing.

The notch, which acts locally as an indentation in the end face, indeed does not directly compromise the flatness of the contact surface. However, in the vicinity of the notch, a local pile up or bulging occurs due to material displacement as a result of the penetrating foreign particle, which compromises the flatness.

Notch damage limits the useful life of a holding device. The regeneration of holding devices results in high costs due to downtimes and due to the processing of the holding device. Therefore, there is an interest in minimising notch damage.

A generally well-known procedure to prevent notch damage consists in providing the end faces of the studs with as hard a protective layer as possible. However, even with a hard protective layer on the end face, notch damage cannot be reliably excluded. Moreover, disadvantages may also arise due to mechanical stresses on the semiconductor wafer. In particular, when the lower side of the semiconductor wafer resting on the contact surface is formed from a hard material, such as SiₓN_{y} or Al₂O₃ for example, the stresses can lead to damage to the semiconductor wafer or the studs.

Other layer configurations for modifying studs, in particular for adjusting hardness and friction properties are also known, whereby single layers or multiple layers can be provided (see [3], [4], [5] and [6]). However, these layers cannot effectively prevent the aforementioned notch damage.

The concept of a buried impact absorption layer is known from packaging technology (see [7], for example). In the event of a surface injury caused by a foreign body on a package with an impact absorption layer, the penetrating foreign body is absorbed by the impact absorption layer and the packaged article is protected. However, since conventional impact absorption layers are made of plastic or cardboard with typical thicknesses in the cm range, bulges occur in the surface of the packaging in the vicinity of the foreign body.

The object of the invention is to provide an improved holding device for holding a structural part and an improved method for manufacturing a holding device for holding a structural part, which avoids disadvantages of conventional techniques. In particular, it is the object of the invention to improve a holding device in such a way that it has a reduced susceptibility to notch damage, has an extended useful life, can be manufactured and used at reduced cost and/or has a reduced tendency to mechanical stresses as a result of impurities, such as particles for example.

This object is achieved by a holding device for holding a structural part and a method for manufacturing a holding device, respectively, which have the features of the independent claims. Preferred embodiments and applications of the invention will be apparent from the dependent claims.

According to a first general aspect of the invention, the above object is achieved by a holding device, which is adapted to hold a structural part, in particular a disc-shaped structural part, such as a semiconductor wafer or a lithography mask for example and comprises a base body, which is formed from at least one board with an upper side, and a plurality of protruding studs, which are arranged on the upper side of the board and form a contact surface with a predetermined flatness for contacting the structural part. According to the invention, on the upper side of the board a notch absorption layer is provided, which has such a low volume density that the notch absorption layer can be compressed by a compaction in the layer volume in the case of mechanical actions by foreign particles, without compromising the flatness of the contact surface, in particular over the contact surface, i.e. towards the upper side of the holding device.

According to a second general aspect of the invention, the above object is achieved by a method for manufacturing a holding device, which is adapted to hold a structural part, in particular a disc-shaped structural part, such as a semiconductor wafer or a lithography mask for example, in which a base body is provided, which is formed from at least one board with an upper side, wherein on the upper side of the board a plurality of protruding studs are arranged, which form a contact surface with a predetermined flatness for contacting the structural part. According to the invention, on the upper side of the board a notch absorption layer is formed, whereby the notch absorption layer has such a low volume density that the notch absorption layer can be compressed by a compaction in the layer volume in the case of mechanical actions by foreign particles, without compromising the flatness of the contact surface. Preferably, the holding device according to the first general aspect of the invention or one of its embodiments is manufactured with the method for manufacturing the holding device according to the second general aspect of the invention or an embodiment of the method.

The holding device can be, for example, an electrostatic holding device (also referred to as an electrostatic wafer panel, electrostatic clamp device, electrostatic clamp, ESC, or electrostatic chuck) or a vacuum holding device (also referred to as a vacuum clamp or vacuum chuck). A spatial direction parallel to the contact surface of the holding device is referred to as the lateral direction and direction perpendicular thereto is referred to as the thickness direction (z direction). In lateral directions, the base body preferably has a planar extent parallel to the contact surface, and it can be formed from one or more boards stacked in the thickness direction and joined to one another. The upper side of the base body is the side that is provided for contacting and holding the structural part. When the holding device is adjusted to contact and hold structural parts on both sides, each side forms an upper side, in which case notch absorption layers are preferably provided on both sides.

The notch absorption layer is a preferably flat layer in the structure of the base body, which flat layer extends parallel to the contact surface, preferably over the entire extent of the contact surface. The notch absorption layer can be a continuous layer or can comprise a plurality of layer sections limited to the lateral extents of the studs, in particular to the extent of the end faces of the studs.

The term “foreign particle” refers to any impurity (foreign substance or defect) that may arise between the contact surface and the structural part to be held, during use of the holding device. An impurity may comprise in particular a particle, for example with a rounded or angular, compact or elongated form, a fibre and/or a composition made of several particles and/or fibres. The impurity may be formed, for example, by material of the structural part to be held, material of the holding device and/or material from the environment. The notch absorption layer is suitable for at least partially accommodating (absorbing) the volume of a foreign particle, in particular protruding defects on the rear side of the structural part.

The structure of the notch absorption layer preferably contains cavities and spaces between the atomic constituents of the material of the notch absorption layer, so that the volume density and optionally also the hardness of the notch absorption layer is reduced in comparison with a material without microscopic gaps. As a result, a foreign particle that is pressed onto the contact surface of the base board with a force component in the thickness direction can locally displace and compress the atomic constituents of the material of the notch absorption layer. The material in the layer volume of the notch absorption layer is compacted and is locally compressed in the vicinity of the foreign particle.

The inventors have found that compaction occurs primarily in the lateral direction and/or in the thickness direction to the depth of the notch absorption layer, while local pile ups in the vicinity of the foreign particle over the thickness of the notch absorption layer are excluded or minimised to a negligible level. Advantageously, the compression of the notch absorption layer does not compromise the flatness of the contact surface. Thus, the notch absorption layer is advantageously distinguished from a conventional impact absorption layer of a package in which surface projections are formed.

A further advantage of the invention is that the notch absorption layer enables reduced susceptibility to notch damage, because volumes of foreign particles are absorbed. Since the flatness is not compromised by foreign particle influences, especially during use of the holding device, the notch absorption layer delivers an extended useful life of the holding device. Furthermore, the invention has the advantage that the notch absorption layer is easy to manufacture, and therefore the costs of the holding device are virtually unchanged in comparison with a conventional holding device, while the costs of using the holding device are considerably reduced on account of shortened downtimes. Finally, mechanical stresses as a result of particles are prevented or reduced to a negligible level.

The term “flatness” refers to the shape tolerance in which the flat contact surface of the holding device is located, whereby tolerance limits are formed by two surfaces parallel to the ideally generated contact surface. Flatness is compromised if the real contact surface generated protrudes through one of the parallel surfaces, in particular through the upper surface remote from the holding device. The tolerance limits are specified as a function of the specific use of the holding device, in particular the desired accuracy of processing, elasticity of the structural part held and elasticity of the studs. The tolerance limits are determined in a localised area, in particular by the flatness on the upper side of the held structural part. For example, they are equal to or smaller than +/−16 nm for a silicon wafer with a thickness of 0.775 mm, in particular equal to or smaller than +/−3 nm for a localised area of 3 mm diameter.

While localised compromises in flatness to the depth of the material, i.e. towards the base body, are not critical for the contact function of the contact surface and can be tolerated, localised compromises in flatness beyond the level of the contact surface, i.e. away from the base body, would be a problem as they can disturb the flatness of the held structural part. By means of the notch absorption layer according to the invention, the flatness is maintained, in particular over the contact surface, by avoiding projections (convexities, build-ups or protuberances) upwards within the specified tolerance.

According to a preferred embodiment of the invention, the notch absorption layer is a porous and/or fibrous layer with columnar growth. The provision of the porous and/or fibrous notch absorption layer has the advantage that the adjustment of the volume density, in particular the porosity or a fibre density or volume between the grains, is simplified during manufacture of the notch absorption layer, for example during a layer deposition from the vapour phase. Preferably, the porosity and/or fibre density is adjusted in such a way that the volume density of the notch absorption layer is selected to be in the range 90% to 10%, in particular in the range 85% to 10%, such as in the range 85% to 50% for example, of the volume density of the solid material of the notch absorption layer. Here, the term “solid material” refers to a single crystal with the same chemical composition and crystal structure as the notch absorption layer, or, if the material of the notch absorption layer does not form a single crystal and/or reliable data are not present, a theoretically defect-free material with the same composition and atomic structure as the notch absorption layer.

Further advantages of the invention emerge from the plurality of configuration variants of the notch absorption layer, so that it can be adjusted optimally to the structure and materials of the other components of the holding device. According to preferred variants, the notch absorption layer can be formed from a ceramic and/or a metal. For example, the notch absorption layer may consist of the ceramic or the metal, or may comprise a multilayer configuration with several ceramics or several metals, or a multilayer configuration with at least one ceramic and at least one metal. For example, the notch absorption layer can be formed from CrₓN with 0.9<x<2.2 or a compound CrₓM_{y}N with 0<x<2.2, in particular 0.3<x<2.2, and 0<y<1, wherein M comprises a further metal, in particular Al, Si or Ti. CrN and CrₓM_{y}N have particular advantages in relation to the adjustment of the volume density of the notch absorption layer. Alternatively or in addition, the notch absorption layer can have a thickness in the range 300 nm to 20 μm, in particular in the range 500 nm to 5 μm.

The notch absorption layer can be formed to be exposed as the uppermost layer on the upper side of the holding device. Alternatively, according to a further advantageous embodiment of the invention, on the upper side of the board a multilayer laminate is provided, which comprises the notch absorption layer and additionally a top layer, which is arranged on the notch absorption layer, an adhesive layer (also referred to as the base layer), which is arranged between the board and the notch absorption layer, and/or a crack mitigation layer, which is adapted to deflect crack propagations. Preferably, the deposition of the multilayer laminate takes place during manufacture of the holding device.

The top layer and/or the adhesive layer can be manufactured, for example, from the same material as the notch absorption layer or from a different material than the notch absorption layer. The top layer and/or the adhesive layer can have a thickness in the range of 10 nm to 20 μm, for example. The crack mitigation layer may be composed of several sub-layers, which are configured for crack mitigation at interfaces between the sub-layers, and/or of a material with an increased fracture strength, such as a metal, for example, that is capable of plastic deformation. The thickness of the crack mitigation layer can be selected to be in the range of 200 nm to 5 μm, for example, or several crack mitigation layers may be provided, which have a cumulative thickness of 200 nm to 5 μm.

Advantageously, the notch absorption layer in a multilayer structure is a layer, preferably an intermediate layer (or preferably in the case of a two-layer structure the lower layer) with the reduced density (in particular with the increased porosity). In the multilayer laminate, the notch absorption layer is compressible/compactable, so that it can absorb the additional volume from the impression of a foreign particle. This function according to the invention is advantageously combined with the function of the at least one further layer in the multilayer laminate, without being impaired by the at least one further layer.

When the multilayer laminate comprises the top layer, the top layer preferably has a greater hardness and a smaller thickness than the notch absorption layer. The inventors have discovered that the notch absorption layer can also absorb a foreign particle without compromising flatness when the harder and thinner top layer is arranged on the notch absorption layer.

Particularly preferably, the top layer and the notch absorption layer are formed from the same material, whereby the top layer has a greater volume density than the notch absorption layer. With this variant, there are advantages for the simplified manufacture of the top layer and the notch absorption layer by means of a single deposition process with varying deposition conditions.

When the multilayer laminate comprises the adhesive layer, the adhesive layer and the notch absorption layer are preferably formed from the same material, whereby the adhesive layer has a greater volume density than the notch absorption layer. With this variant, there are also advantages for the simplified manufacture of the adhesive layer and the notch absorption layer.

In terms of the method, the deposition of the multilayer laminate can preferably comprise the formation of the top layer and/or the adhesive layer, whereby the top layer and/or the adhesive layer are formed from the same material as the notch absorption layer, and during the deposition of the multilayer laminate, process parameters of the deposition are altered in such a way that the notch absorption layer is formed with a lower volume density than the top layer and/or the adhesive layer.

According to a further advantageous embodiment of the invention, the notch absorption layer is arranged on end faces of the studs. The notch absorption layer is located close to or on the free ends of the studs facing away from the at least one board of the holding device, which free ends span the contact surface of the holding device. In this variant of the invention, the notch absorption layer is preferably deposited on the studs, which can be manufactured from the same material as the board, for example. First of all, the base body with the board and the studs on the upper side of the board are preferably provided and the notch absorption layer is formed on end faces of the studs. The notch absorption layer or a top layer provided on the notch absorption layer forms the contact surface of the structural part to be held. This embodiment has the advantage that a holding device known per se can be equipped simply with the notch absorption layer. Furthermore, the regeneration of the holding device, which may be necessary after a period of operation, is facilitated in particular with a renewal of the notch absorption layer.

According to an alternative advantageous embodiment of the invention, the abovementioned multilayer laminate is provided and the notch absorption layer is part of the multilayer laminate, whereby the multilayer laminate is structured in such a way that the studs are formed by the multilayer laminate. Advantageously, in this case the studs are formed exclusively by the multilayer laminate. In terms of the method, the base body with the board without studs on the upper side is preferably first provided, after which the multilayer laminate is deposited on the upper side of the board, and then the multilayer laminate is structured in such a way that the studs on the upper side of the board are formed by the multilayer laminate.

A further advantage of the invention is that the notch absorption layer can be manufactured simply and different deposition methods are available for manufacturing the notch absorption layer. Preferably, the notch absorption layer is formed by means of reactive magnetron sputtering. Reactive magnetron sputtering has the particular advantage that, by adjusting the sputtering conditions, the volume density of the notch absorption layer, and where appropriate further layers in a multilayer laminate, can be adjusted easily.

### BRIEF DESCRIPTION OF THE DRAWINGS

Further details and advantages of the invention will be described below with reference to the accompanying drawings. In the diagrammatic drawings:

FIG. 1: shows features of preferred embodiments of the holding device according to the invention;

FIG. 2: shows a variant of the invention, in which the notch absorption layer is formed on studs of the holding device;

FIG. 3: shows a variant of the invention, in which the studs of the holding device are formed by the notch absorption layer; and

FIG. 4: shows an experimental test result, which was obtained with the notch absorption layer according to the invention.

### DETAILED DESCRIPTION

Features of embodiments of the invention will be described below by way of example with reference to the formation, arrangement and function of the notch absorption layer. Features of the holding device for semiconductor wafers, which are equipped with the notch absorption layer, such as details of the base body for example, cooling or an electrode apparatus, will not be described, as they are known per se from conventional holding devices. The invention is not limited to holding devices for semiconductor wafers, but rather can also be used in a corresponding manner in holding devices for other structural parts, such as for glass plates or lithography masks, for example.

The invention is not limited to the materials, dimensions and forms specified by way of example. In particular, the notch absorption layer can be formed from a different material than the CrN specified by way of example.

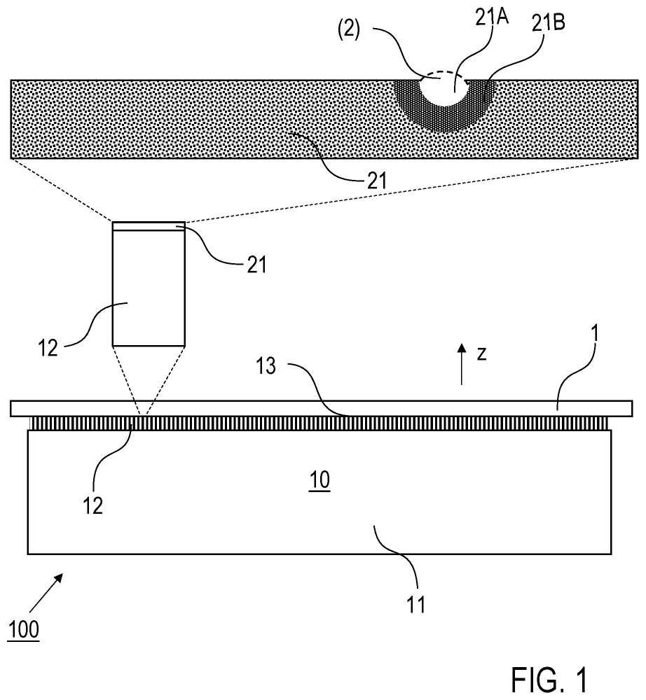

Shown diagrammatically in the lower portion of FIG. 1 is a holding device 100 for holding a semiconductor wafer 1, which, in a manner known per se, has a base body 10 with a board 11 and a plurality of studs 12. The end faces of the studs 12 projecting in the z direction span the contact surface 13 of the holding device 100 for accommodating the semiconductor wafer 1. The side of the board 11 on which the semiconductor wafer 1 rests is the upper side of the board 11. The board 11 is manufactured from an SiSiC glass composite, for example, and the studs 12 are manufactured from glass or ceramic, for example. It is emphasised that FIG. 1 is a diagrammatic depiction. In a practical example, the studs have a height of 10 μm, a width of 220 μm and a spacing of 1.5 mm, for example. One of the studs 12 is shown diagrammatically enlarged in the middle portion of FIG. 1.

The notch absorption layer 21 is arranged at the upper end of the studs 12 in each case. In the example depicted, the notch absorption layer 21 is the uppermost layer, so that the end faces and the entire contact surface 13 are spanned by all layer sections of the notch absorption layer 21 on the studs 12.

In the upper portion of FIG. 1, the notch absorption layer 21 and its action are illustrated further enlarged. The notch absorption layer 21 consists of porous CrN with a thickness of 3 μm, for example. When the semiconductor wafer 1 is put in place, if a foreign particle 2 (not shown) is present on the contact surface of the semiconductor wafer 1 or the surface of the notch absorption layer 21, the foreign particle 2 is pressed into the notch absorption layer 21. This results in an indentation 21A, which is not critical for the function of the holding device 100, in particular for the flat contact of the semiconductor wafer 1. In the vicinity of the indentation 21A, the material of the notch absorption layer 21 is compressed by the pressed-in foreign particle 2, so that an upward projection is avoided and the upward flatness of the contact surface 13 is not compromised. The foreign particle 2 may remain stuck in the notch absorption layer 21, may remain stuck to the rear side of the wafer or may be removed by cleaning the surface.

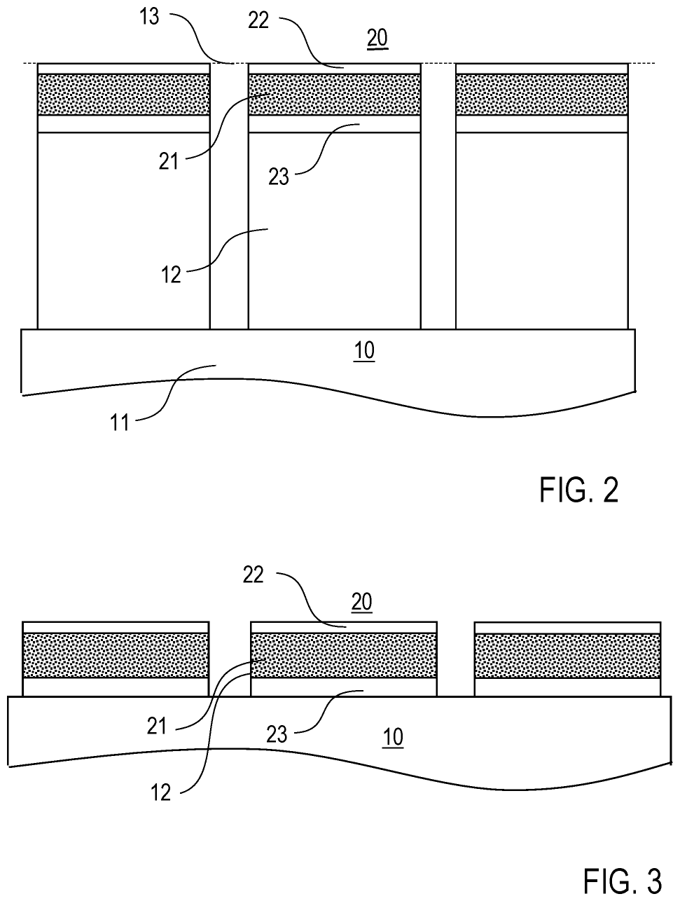

Deviating from the notch absorption layer 21 as a single layer according to FIG. 1, a multilayer laminate 20 can be provided, as illustrated in FIGS. 2 and 3. In the multilayer laminate 20, the notch absorption layer 21 is embedded between a top layer 22 and an adhesive layer 23. According to FIG. 2, the multilayer laminate 20 is deposited on the upper side of the studs 12, while according to FIG. 3 the studs 12 are formed by the multilayer laminate 20.

Deviating from the illustrations, the multilayer laminate 20 can comprise only two layers or more than three layers. The layers can be formed from the same materials or from different materials. In particular, in the case of the embodiment according to FIG. 3, it may be advantageous to form the multilayer laminate 20 with further and/or thicker layers, in order to achieve the desired stud height.

In a first example, the layers in the multilayer laminate 20 comprise the adhesive layer 23 made of CrN with a thickness of 5.5 μm, the notch absorption layer made of porous CrN with a thickness of 3 μm and the top layer 22 made of CrN with a thickness of 1.5 μm. In a second example, the adhesive layer 23 is manufactured from CrN with a thickness of 0.1 μm, the notch absorption layer is manufactured from porous CrN with a thickness of 3 μm and the top layer 22 is manufactured from CrN with a thickness of 1.4 μm. The top layer 22 has the hardness and the tribological properties of a CrN top layer, as is known from conventional holding devices. The hardness of the adhesive layer 23 can selected to be equal to or greater than the hardness of the top layer 22. The notch absorption layer 21 has the lowest hardness on account of its porosity.

The layers 21, 22 and 23 are manufactured with reactive magnetron sputtering, for example. The difference in hardness between the layers is adjusted via the partial pressure (/gas flow) of the sputtering gas Ar and the reactive gas N₂. With an increasing sputtering gas content, the deposited layer becomes more porous, and/or fibrous in its microstructure.

The inventors have investigated the properties of the multilayer laminate 20 according to the first example and those of conventional single CrN top layers with thicknesses of 1.2 μm and 10 μm when under the impact of a test tool with a hard tip by means of AFM measurements. The conventional CrN top layers resulted in convexities of more than 170 nm up to 300 nm in the z direction and cracks as well as indentations in the range of about 1 μm to 2.1 μm when the tip was pressed in with propulsive forces of 100 mN and 200 mN. Under identical test conditions, the multilayer laminate 20 advantageously gave convexities of less than 50 nm and no cracks and also indentations in the range of about 1.6 μm to 2.2 μm. These results show that the flatness is substantially less compromised by the absorption effect of the notch absorption layer 21 and particles can be effectively absorbed by the notch absorption layer 21.

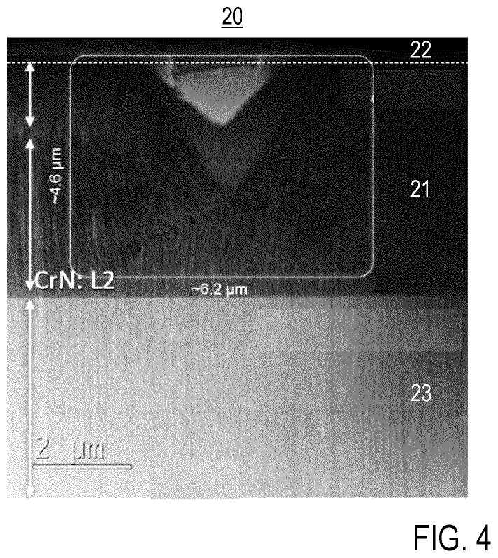

By way of example, FIG. 4 shows the effect of the impression of the test tool using a TEM sectional image of the multilayer laminate 20 according to the first example. The tip of the test tool penetrates the top layer 22 and displaces and compresses the material of the notch absorption layer 21, while the adhesive layer 23 remains unaltered.

The features of the invention disclosed in the above description, the drawings and the claims may be of importance both individually and in combination or sub-combination for the realisation of the invention in its various configurations.

1. A holding device which is adapted to hold a structural part, the holding device comprising:
a base body comprising at least one board with an upper side, and
a plurality of protruding studs arranged on the upper side of the board and forming a contact surface with a predetermined flatness for contacting the structural part,
the upper side of the board being provided with a notch absorption layer which has a volume density such that the notch absorption layer can be compressed by a compaction in the layer volume in the case of mechanical actions by foreign particles, without compromising the flatness of the contact surface.

2. (canceled)

3. The holding device according to any claim 1, in which
the notch absorption layer is formed from a ceramic or a metal or a ceramic and a metal.

4. (canceled)

5. The holding device according to claim 20, in which
the multilayer laminate comprises the top layer, and wherein the top layer has a greater hardness and a smaller thickness than the notch absorption layer.

6. The holding device according to claim 5, in which
the top layer and the notch absorption layer are formed from the same material, and wherein the top layer has a greater volume density than the notch absorption layer.

7. The holding device according to claim 20, in which
the multilayer laminate comprises the adhesive layer, wherein the adhesive layer and the notch absorption layer are formed from the same material and the adhesive layer has a greater volume density than the notch absorption layer.

8. The holding device according to claim 1, in which
the notch absorption layer is arranged on end faces of the studs.

9. The holding device according to claim 20, in which
the multilayer laminate is structured in such a way that the studs are formed by the multilayer laminate.

10. A method for manufacturing a holding device adapted to hold a structural part comprising
providing a base body, which is formed from at least one board with an upper side, a plurality of protruding studs being arranged on the upper side of the board, which form a contact surface with a predetermined flatness for contacting the structural part, and
forming a notch absorption layer on the upper side of the board, wherein the notch absorption layer has a volume density such that the notch absorption layer can be compressed by a compaction in the layer volume in the case of mechanical actions by foreign particles, without compromising the flatness of the contact surface.

11. The method according to claim 10, in which
forming the notch absorption layer is performed using reactive magnetron sputtering.

12. The method according to claim 10,
further comprising depositing a multilayer laminate on the upper side of the board, wherein the multilayer laminate comprises the notch absorption layer and at least one of a top layer, which is arranged on the notch absorption layer, an adhesive layer, which is arranged between the board and the notch absorption layer, and a crack mitigation layer, which is adapted to deflect crack propagations.

13. The method according to claim 12, in which
the deposition of the multilayer laminate comprises formation of the top layer and/or the adhesive layer,
the top layer and/or the adhesive layer are formed from the same material as the notch absorption layer, and
during the depositing of the multilayer laminate, process parameters of the depositing are altered in such a way that the notch absorption layer is formed with a lower volume density than the top layer and/or the adhesive layer.

14. The method according to claim 10, in which
the base body is provided with the board and the studs on the upper side of the board, and
the notch absorption layer is arranged on end faces of the studs.

15. The method according to claim 12, in which
the base body is provided with the board without studs on the upper side of the board,
the multilayer laminate is deposited on the upper side of the board, and
the multilayer laminate is structured in such a way that the studs are formed on the upper side of the board by the multilayer laminate.

16. The holding device according to claim 1, in which the notch absorption layer is one of a porous layer, fibrous layer, or a porous and fibrous layer.

17. The holding device according to claim 1, in which the volume density of the notch absorption layer is selected to be in the range of 90% to 10% of the volume density of a solid material of the notch absorption layer.

18. The holding device according to claim 1, in which the notch absorption layer is formed from CrxN with 0.9<x<2.2 or from a compound CrxMyN with 0<x<2.2 and 0<y<1, wherein M comprises a further metal taken from the group consisting of Al, Si and Ti.

19. The holding device according to claim 1, in which the notch absorption layer has a thickness in the range of 300 nm to 20 μm.

20. The holding device according to claim 1, in which the upper side of the board is provided with a multilayer laminate which includes the notch absorption layer and at least one of a top layer which is arranged on the notch absorption layer, an adhesive layer arranged between the board and the notch absorption layer, and a crack mitigation layer which is adapted to deflect crack propagations.
